(19) United States
(12) Patent Application Publication
(10) Pub. No.: US 2012/0241204 A1
(43) Pub. Date: Sep. 27, 2012

(54) THIN FILM CAPACITOR, MOUNTING SUBSTRATE, AND METHOD OF MANUFACTURING THE MOUNTING SUBSTRATE

(75) Inventors: Katsuji Matsumoto, Kanagawa (JP); Shusaku Yanagawa, Kanagawa (JP); Satoshi Horiuchi, Kanagawa (JP); Shuichi Oka, Kanagawa (JP)

(73) Assignee: SONY CORPORATION, Tokyo (JP)

(21) Appl. No.: 13/426,709

(22) Filed: Mar. 22, 2012

(30) Foreign Application Priority Data
Mar. 21, 2011 (JP) 2011-079816

(51) Int. Cl. H05K 1/16; H01G 4/33; H05K 1/03

(52) U.S. Cl. 174/258; 361/301.1; 174/260; 156/293

(57) ABSTRACT

A thin film capacitor includes: two electrode layers; a dielectric film interposed between the two electrode layers; an opening that pierces through, together with the dielectric film, in the thickness direction, any one of the two electrode layers or a conductive layer in the same level adjacent to one of the two electrode layers; and a reinforcing member that couples, in the opening, a side surface of the dielectric film to a side surface of the one electrode layer or the conductive layer.

### FIELD

The present disclosure relates to a thin film capacitor in which a dielectric film is interposed between two conductive layers, a mounting substrate incorporating the thin film capacitor, and a method of manufacturing the mounting substrate.

### BACKGROUND

An increase in frequency and an increase in speed are requested for a capacitative device (a capacitor) formed in a semiconductor integrated circuit.

On the other hand, in a mounting substrate such as a printed wiring board, a single component (a capacitor component) functioning as a capacitative device is mounted on the surface of the mounting substrate.

A capacitance value of the capacitative device mounted as the single component is extremely larger than a capacitance value of a capacitative device that can be formed in the semiconductor integrated circuit. Therefore, it is practically impossible to replace the capacitative device mounted as the single component with the capacitative device in the semiconductor integrated circuit.

Therefore, a capacitative device having a relatively large capacitance value is often mounted on the mounting substrate as a single component. On the other hand, a capacitative device requested to have a high operating frequency and high speed is formed in the semiconductor integrated circuit as a thin film capacitor.

In recent years, the number of single components in use is increasing according to the improvement of functions of electric devices. On the other hand, in order to reduce the sizes of electronic devices such as a cellular phone and a small information device, there is an increasing demand for an increase in functions and a reduction in size of the mounting substrate. In order to meet this demand, the development of techniques explained below is in progress.

For example, as described in JP-A-2003-152303, a technique for embedding a capacitative device as a single component in a mounting substrate is proposed.

A technique for directly forming a capacitative device in a mounting substrate using a thin film attracts attention. A manufacturing method for a mounting substrate for forming a capacitative device on the inside is described in, for example, JP-A-2007-12667.

According to the description of JP-A-2007-12667, a dielectric film of a thin film is formed on a wire of amounting substrate and an electrode film is formed on the dielectric film.

### SUMMARY

However, in the technique described in JP-A-2003-152303, since a certain degree of height is necessary, a space, in particular, a space in the height direction is necessary over plural layers of a multi-layer wiring board.

On the other hand, in the technique described in JP-A-2007-12667, an increase in the thickness of the mounting substrate can be suppressed by forming the capacitative device with the thin film. The capacitative device can be formed under other components such as an IC mounted on the surface of the mounting substrate. Therefore, it is possible to reduce the size and the thickness of the mounting substrate.

However, in the technique described in JP-A-2007-12667, adhesion between the dielectric film and upper and lower electrodes is extremely weak because of the influence of stress or the like in a manufacturing process for the substrate. Therefore, peeling tends to occur between the dielectric film and electrode layers.

The adhesion between the dielectric film and the electrode layers can be improved by forming unevenness on the surfaces of the electrodes to impart an anchor effect to the electrodes.

However, when the unevenness is formed on the surfaces of the electrodes, the dielectric film needs to be increased in thickness because of a reason such as a reduction in leakage. In this case, when a necessary capacitance value is obtained, a capacitor area increases and fluctuation in capacitance increases. Further, yield is deteriorated, leading to an increase in manufacturing cost.

Therefore, it is desirable to provide a thin film capacitor having a structure for preventing peeling between a dielectric film and upper and lower electrodes even when applied to a mounting substrate incorporating a capacitative device.

It is also desirable to provide a mounting substrate incorporating such a thin film capacitor having the peeling preventing structure and a method of manufacturing the mounting substrate.

An embodiment of the present disclosure is directed to a thin film capacitor including: two electrode layers; a dielectric film interposed between the two electrode layers; an opening that pierces through, together with the dielectric film, in the thickness direction, anyone of the two electrode layers or a conductive layer in the same level adjacent to the one of the two electrode layers; and a reinforcing member that couples, in the opening, a side surface of the dielectric film to a side surface of the one electrode layer or the conductive layer.

Another embodiment of the present disclosure is directed to a mounting substrate including a laminated structure in which conductive films and insulating films are alternately laid one on top of another. A thin film capacitor is formed in the laminated structure. The thin film capacitor includes: two electrode layers; a dielectric film interposed between the two electrode layers; an opening that pierces through, together with the dielectric film, in the thickness direction, any one of the two electrode layers or a conductive layer in the same level adjacent to the one of the two electrode layers; and a reinforcing member that couples, in the opening, a side surface of the dielectric film to a side surface of the one electrode layer or the conductive layer.

Still another embodiment of the present disclosure is directed to a method of manufacturing a mounting substrate, including: laminating a conductive layer functioning as a first electrode layer, a dielectric film layer, and a conductive layer functioning as a second electrode layer and forming a thin film capacitor material through formation of the first electrode layer by processing of one of the conductive layers; sticking together the thin film capacitor material with a core substrate from the side of the first electrode layer; opening, in the thin film capacitor material before or after the sticking together, the conductive layer of one of the first electrode layer and the second electrode layer or a conductive layer in the same level adjacent to the conductive layer and forming an opening to pierce through at least the dielectric film in the thickness direction; and forming, in the thin film capacitor material, a reinforcing member that couples a sidewall in the opening of the conductive layer of any one of the first electrode layer and the second electrode layer or the conductive layer in the same level and a sidewall in the opening of the dielectric film.

With the configuration explained above, the opening is provided near the thin film capacitor material to prevent peeling due to the influence of stress. In the opening, the reinforcing member that couples the side surface in the opening of the dielectric film and the side surface in the opening of the conductive film is formed. Therefore, according to the action of the reinforcing member, film peeling on an interface between the dielectric film and the conductive film less easily occurs.

In the method of manufacturing a mounting substrate, adhesion strength between the dielectric film of the thin film capacitor material and the conductive film is high. Therefore, it is possible to prevent peeling between the dielectric film and the first or second electrode layer due to stress or the like in a manufacturing process.

According to the technique of the embodiments of the present disclosure, even when the technique is applied to a mounting substrate incorporating a capacitative device, it is possible to prevent peeling between a dielectric film and upper and lower electrodes.

### BRIEF DESCRIPTION OF THE DRAWINGS

FIGS. 1A to 1C are schematic plane views for explaining the transition of a form of a substrate in a process of manufacturing a mounting substrate;

FIG. 2 is a sectional view of a schematic structure (a basic device structure) of a thin film capacitor;

FIGS. 3A and 3B are a schematic sectional view and a transparent plane view of a comparative structure example;

FIGS. 4A and 4B are a sectional view and a transparent plane view of a thin film capacitor portion of a mounting substrate according to a first embodiment;

FIGS. 5A to 5C are sectional views in a manufacturing process for the mounting substrate according to the first embodiment;

FIGS. 6A and 6B are sectional views of the mounting substrate in the manufacturing process following FIGS. 5A to 5C;

FIGS. 7A and 7B are sectional views of the mounting substrate in the manufacturing process following FIGS. 6A and 6B;

FIGS. 8A and 8B are a sectional view and a transparent plane view of a thin film capacitor portion of a mounting substrate according to a second embodiment;

FIGS. 9A and 9B are a sectional view and a transparent plane view of a thin film capacitor portion of a mounting substrate according to a third embodiment;

FIGS. 10A to 10C are sectional views in a manufacturing process for a mounting substrate according to a fourth embodiment;

FIGS. 11A to 11C are sectional views of the mounting substrate in the manufacturing process following FIGS. 10A to 10C;

FIGS. 12A to 12C are sectional views in a manufacturing process for a mounting substrate according to a fifth embodiment;

FIGS. 13A to 13C are sectional views of the mounting substrate in the manufacturing process following FIGS. 12A to 12C;

FIG. 14 is a sectional view of a mounting substrate according to a sixth embodiment;

FIG. 15 is a sectional view of a mounting substrate according to a seventh embodiment;

FIG. 16 is a sectional view of a mounting substrate according to an eighth embodiment;

FIG. 17 is a sectional view of a mounting substrate according to a ninth embodiment;

FIG. 18 is a transparent plane view of a mounting substrate according to a modification 1; and

FIG. 19 is a transparent plane view of another mounting substrate according to the modification 1.

### DETAILED DESCRIPTION

Embodiments (thin film capacitor structures) of the technique of the present disclosure are explained below with reference to the accompanying drawings in an example in which a thin film capacitor to which the technique is applied is formed in a mounting substrate. The thin film capacitor structures of the technique of the present disclosure can also be applied when the thin film capacitor is formed in a semiconductor integrated circuit.

The embodiments are explained in order described below.

1. A manufacturing technique example and a basic device structure are explained.

2. A comparative structure example is explained.

3. A structure in which openings are formed in a conductive film in the same level adjacent to an electrode of a thin film capacitor and a manufacturing example of the structure are explained as a first embodiment.

4. A structure in which openings are provided on the inside of a capacitor is explained as a second embodiment.

5. An example in which the openings provided on the inside as in the second embodiment are used as electrode vias is explained as a third embodiment.

6. Another manufacturing method is explained as a fourth embodiment.

7. Still another manufacturing method is explained as a fifth embodiment.

8. Another structure of openings and a reinforcing member is explained as a sixth embodiment.

9. Still another structure of openings and a reinforcing member is explained as a seventh embodiment.

10. Still another structure of openings and a reinforcing member is explained as an eighth embodiment.

11. Still another structure of openings and a reinforcing member is explained as a ninth embodiment.

12. Modification 1 is explained.

13. Other modifications are explained.

### 1. A Manufacturing Technique Example and a Basic Device Structure

First, a manufacturing technique example that can be adopted in forming a thin film capacitor in a mounting substrate and a basic device structure are explained with reference to the drawings.

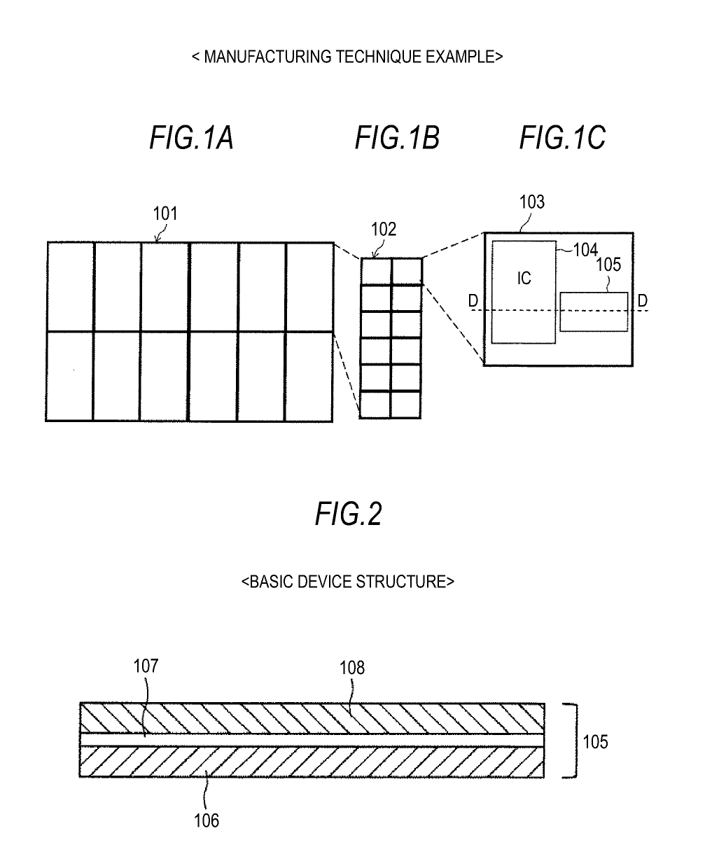

The transition of a form of a substrate in a process for manufacturing a mounting substrate is shown in FIGS. 1A to 1C.

The mounting substrate in this example is manufactured as a large substrate called work 101 shown in FIG. 1A. The work 101 is formed by arraying plural substrates of an intermediate size called frame 102 shown in FIG. 1B. The frame 102 is formed by arraying plural module substrates (hereinafter simply referred to as mounting substrate 103) further divided into pieces of a smaller size shown in FIG. 1C.

In the manufacturing process, plural (6×2) frames 102 are separated from the work 101.

In a state of the frame 102, an electronic component such as an IC 104 is mounted on a substrate surface. After the component is mounted, the frame 102 is separated into plural (2×6) mounting substrates 103 shown in FIG. 1C by dicing or the like. A thin film capacitor 105 is formed on the inside of the mounting substrate 103 in advance.

A schematic structure (a basic device structure) of the thin film capacitor 105 is shown in FIG. 2.

The thin film capacitor 105 basically has a so-called MIM structure in which a dielectric film 107 is held between two electrode layers (106 and 108). In the following explanation, a forming film of the lower first electrode layer 106 is referred to as metal foil and a forming film of the upper second electrode layer 108 is referred to as conductive film. However, these names do not limit thicknesses of the metal foil (the first electrode layer 106) and the conductive film (the second electrode layer 108) in that the metal foil is thinner than the conductive film. Examples of the thicknesses and materials are explained later.

The thin film capacitor 105 is formed in a process of manufacturing the work 101 or a process of manufacturing the frame 102.

As an example, in the process of manufacturing the frame 102, the thin film capacitor 105 is formed by, for example, sticking together device materials in regions to be formed as the mounting substrates 103. The number of thin film capacitors 105 in the regions to be formed as the mounting substrates 103 is an arbitrary number equal to or larger than one. The thin film capacitor 105 can also be formed in the process of manufacturing the work 101.

First, a comparative structure example of the thin film capacitor 105 is explained below. Subsequently, structure examples (first to tenth embodiments) of the technique of the present disclosure are explained to clarify characteristics in comparison with the comparative structure example.

### 2. Comparative Structure Example

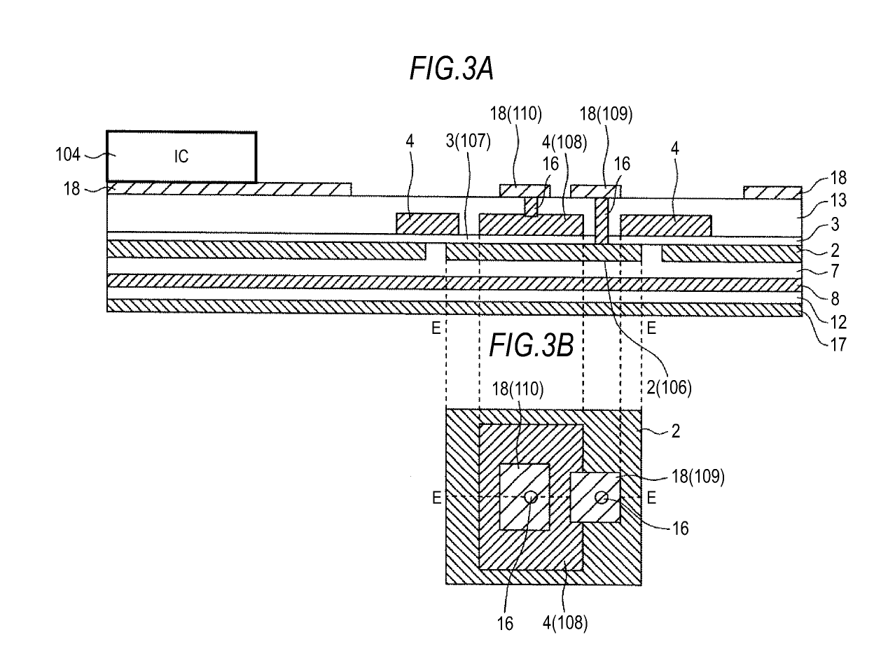

FIG. 3A is a schematic sectional view of the comparative structure example taken along line D-D in FIG. 1C.

The mounting substrate 103 shown in FIG. 3A basically has a laminated structure in which insulating films formed of a material such as resin having high fluidity during heating called prepregs are interposed and laminated among plural conductive films. The conductive film is called and described in a name such as metal foil (copper foil, etc.). However, the name does not limit thickness in that the metal foil is thinner than other conductive films not called metal foil. In all sectional views referred to below including FIG. 3A, the conductive films are hatched and the insulating films (prepregs) among the conductive films are not hatched.

More specifically, a conductive film 17, a prepreg 12, a copper foil 8, a prepreg 7, a metal foil 2, a dielectric film 3, a prepreg 13, and a conductive film 18 are laminated in order from on the opposite side (for convenience of explanation, referred to as lower surface side) of a side on which the IC 104 is mounted.

As a method of manufacturing the mounting substrate, a method substantially common to a method according to a first embodiment explained later can be adopted. Therefore, explanation of the manufacturing method is omitted.

FIG. 3B is a transparent plane view taken along line E-E in FIG. 3A. In the transparent plane view, the inside of the substrate is seen through except an electrode pad formed of the conductive film 18 on the top surface in a plane view of the portion of the thin film capacitor 105 seen from the side on which the IC 104 is mounted.

As explained in detail in a manufacturing method explained later, a three-layer member (an device forming material) shown in FIG. 2 functioning as the thin film capacitor 105 is formed in a large sheet shape in advance. The sheet-like three-layer member is stuck together with a mounting substrate being formed, whereby a layer functioning as the thin film capacitor 105 is supplied to the mounting substrate. A part of layers such as an electrode layer located on a sticking together surface side is subjected to patterning in advance in a state of a sheet before the sticking together. After the sticking together, patterning is applied to other electrode layers and the like located on the front surface side. After the patterning of the electrode layers, the prepreg 13 is formed. After processing of through-vias or the like as appropriate, the conductive film 18 is formed and processed on a mounting surface.

In general, a capacitance value of a capacitative device such as a thin film capacitor can be represented as indicated by Expression (1) below. Concerning signs in Expression (1), C represents a capacitance value, ∈0 represents a dielectric constant in the vacuum, ∈ represents a relative dielectric constant of a dielectric material in use, S represents an electrode area, and T represents the thickness of a dielectric film.

C=∈0·∈·S/T (1)

In order to obtain a high capacitance value for the purpose of reducing the size of the capacitative device, it is effective to reduce the thickness of the dielectric film and adopt a dielectric material having a high relative dielectric constant.

As a method of forming such a dielectric film of a thin film on the mounting substrate, a film forming technique such as a sol-gel method, an aerosol method, or a sputtering method can be applied.

In order to reduce the thickness of the dielectric film of the capacitative device, the dielectric film needs to be a film material having a low leak current and high withstanding pressure. Therefore, it is requested that impurities and the like due to the film forming material of the dielectric film do not remain in the film. Further, the impurities also cause deterioration of the relative dielectric constant. From this viewpoint, it is also requested that the impurities do not remain in the film. In order to suppress the remaining of the impurities, it is desirable to form the film at higher temperature.

As the dielectric material having a high relative dielectric constant, a crystalline dielectric material such as strontium titanate (SrTiO₃:STO), barium titanate (BaTiO₃: BTO), barium strontium titanate (BST), or lead titanate zirconate (PZT) is used.

Since the relative dielectric constant of such a crystalline dielectric material depends on crystallinity thereof, in order to attain a high dielectric constant, it is desirable to form the dielectric material at higher temperature.

On the other hand, among materials for forming the mounting substrate, materials having heat resistant temperature of about 200° C. (e.g., a prepreg) are widely used. It is difficult to form a dielectric film at high temperature on mounting substrates formed of these materials.

In order to realize the formation of a dielectric film at high temperature, it is desirable to adopt a manufacturing method for forming, separately from a mounting substrate, through a film forming process at high temperature, a three-layer film material of a thin film capacitor in which a dielectric film is formed on a metal foil and an electrode layer is further formed on the dielectric film and sticking the formed three-layer film material to the mounting substrate. In this manufacturing method, compared with a method of sequentially forming the three-layer film material of the thin film capacitor on the mounting substrate, the temperature during the film formation of the thin film capacitor can be raised. The above-mentioned various high dielectric materials can be adopted. Therefore, a thin film capacitor having a large capacitance value per a unit area can be formed in the mounting substrate.

Immediately after the three-layer film material of the thin film capacitor is stuck to the mounting substrate, a conductive film denoted by reference numeral 4 in FIG. 3A is not patterned yet. The prepreg 13 and the conductive film 18 are not formed yet. In this state, a mask layer such as a resist is formed on the conductive film 4. The conductive film 4 is patterned by etching or the like. Thereafter, the resist or the like is peeled off and then the conductive film 4 is covered with the prepreg 13. The conductive film 18 is formed on the prepreg 13.

In a state in which such a thin film capacitor is formed on the mounting substrate and the prepreg 13 is filled, because of, for example, a difference between the numbers of members on the front and rear surfaces, a stress difference between the front surface side and the rear surface side is increased by thermal expansion or the like of the members during heating.

Therefore, peeling tends to occur on an interface between the dielectric film 3 and the metal foil 2 or an interface between the dielectric film 3 and the conductive film 4. When peeling occurs, for example, because leakage or the like increases, device characteristics are not guaranteed and connection to an electrode pad formed of the conductive film 18 is insufficient. Therefore, device yield is deteriorated and, depending on a degree of the deterioration, it is difficult to continue the substrate manufacturing.

Improvement of adhesion can be realized by, for example, forming fine unevenness on the surface of the metal foil 2 functioning as the first electrode layer 106 and imparting an anchor effect to the metal foil 2. However, in this case, it is necessary to increase the thickness of the dielectric film 3 in order to prevent leakage in the uneven section. An area for obtaining a desired capacitance value increases and a capacitance value tends to fluctuate. As a result, yield is deteriorated, leading to an increase in cost.

In the technique of the embodiment of the present disclosure, a thin film capacitor including a structure in which film peeling is less easily caused and a method of manufacturing the thin film capacitor are provided.

The thin film capacitor in the technique of the embodiment of the present disclosure has openings that pierce through one electrode layer of the first electrode layer 106 and the second electrode layer 108 in the thickness direction together with the dielectric film 107 (3). The openings may pierce through a conductive layer in the same level adjacent to any one of the first electrode layer 106 and the second electrode layer 108 together with the dielectric film 107 (3).

In both the cases, in the technique of the embodiment of the present disclosure, the thin film capacitor includes a reinforcing member that couples a side surface of the dielectric film 107 (3) to a side surface of the one electrode layer or the conductive layer in the same level in the openings. The conductivity and the insulating properties of the reinforcing member do not matter.

FIGS. 3A and 3B are referred to again taking into account the characteristics of the technique of the embodiment of the present disclosure.

In the comparative structure example shown in FIGS. 3A and 3B, the metal foil 2 functioning as the first electrode layer 106 and the conductive film 4 functioning as the second electrode layer 108 respectively have openings. However, since these openings are opened in the dielectric film 3 (107) as well, the prepreg 7 or 13 for filling the openings does not function as a reinforcing member. Therefore, the metal foil functioning as the first electrode layer 106 and the conductive film 4 functioning as the second electrode layer 108 tend to cause film peeling on interfaces with the dielectric film 107 (3).

More specific embodiments are explained below with reference to the drawings.

### 3. First Embodiment

### [Device Structure]

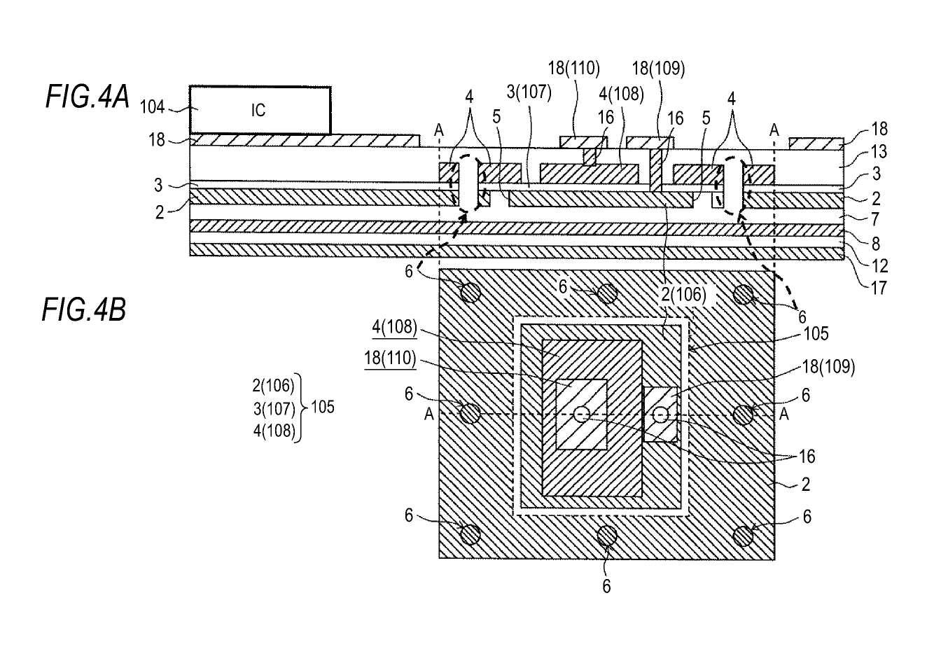

FIG. 4A is a sectional view of a thin film capacitor portion of a mounting substrate according to a first embodiment. The sectional view corresponds to a portion taken along line D-D in FIG. 1C. FIG. 4B is a transparent plane view taken along line A-A in FIG. 4A. The meaning of the transparent plane view is the same as the meaning of FIG. 3B with respect to FIG. 3A.

As shown in FIG. 4A, the conductive film 17, the prepreg 12, the copper foil 8, the prepreg 7, the metal foil 2, the dielectric film 3, the prepreg 13, and the conductive film 18 are laminated from the lower surface side to form the mounting substrate. This is the same as the comparative structure example shown in FIGS. 3A and 3B.

In the mounting substrate, the first electrode layer 106 formed of the metal foil 2 is arranged as a lower electrode of a capacitor. The first electrode layer 106 has a rectangular plane shape as shown in FIG. 4B. In the mounting substrate, the second electrode layer 108 formed of the conductive film 4 is arranged as an upper electrode of the capacitor. The second electrode layer 108 has a rectangular plane shape slightly larger than the first electrode layer 106.

In this example, a conductive layer (the conductive film 4) in the same level as the second electrode layer 108 is arranged to surround the thin film capacitor 105. The conductive layer (the conductive film 4) is electrically and physically separated from the second electrode layer 108. The conductive layer (the conductive film 4) is formed together with the second electrode layer 108 by processing the conductive film 4. The conductive layer (the conductive film 4) may be fixed in terms of potential at, for example, GND potential. However, for example, when the conductive layer (the conductive film 4) overlaps the edge of the first electrode layer 106 via the dielectric film 3 (107) as in this example, it is more desirable to make the conductive layer (the conductive film 4) floating in terms of potential.

As in a modification explained later, the conductive layer (the conductive film 4) may be a wire or the like around the capacitor. In the case of the wire, the wire may be a signal wire if the influence on the capacitor can be neglected. However, a voltage wire, in particular, a GND wire is desirable. In particular, when the conductive layer (the conductive film 4) is the wire around the capacitor, it is rather desirable that an overlapping portion indicated by a broken line around the first electrode layer 106 in FIG. 4B is absent.

As shown in FIG. 4B, the second electrode layer 108 is arranged to fit in the outer edge of the first electrode layer 106 slightly larger than the second electrode layer 108. Consequently, the thin film capacitor 105 having the size of the second electrode layer 108 substantially as an effective area is formed.

The dielectric film 3 (107) interposed between the first electrode layer 106 and the second electrode layer 108 is formed over substantially the entire region except the openings provided as appropriate. It is not indispensable that the dielectric film 3 (107) is formed over the entire region. However, when a sheet-like capacitor material having a three-layer structure explained later is separately formed, in general, the dielectric film 3 (107) is present over the substantially the entire region of the sheet.

Although not shown in the transparent plane view of FIG. 4B, a conductive layer (the metal foil 2) surrounding the thin film capacitor 105 is arranged around the first electrode layer 106 as well by the metal foil 2 in the same level as the first electrode layer 106. In the case of this example, any one of the conductive layer (the metal foil 2) and the conductive layer (the conductive film 4) only has to be present. Like the conductive layer (the conductive film 4), the conductive layer (the metal foil 2) is electrically and physically separated from the capacitor electrode layer and fixed in terms of potential or set in a floating state.

The prepreg 7 having fluidity during heating is filled between the metal foil 2 including the first electrode layer 106 and the copper foil 8.

The prepreg 13 having fluidity during heating is filled around the conductive film 4 including the second electrode layer 108.

The conductive layer (the conductive film 4) arranged around the thin film capacitor 105 has plural openings 6, for example, at equal intervals.

Since the openings 6 are formed simultaneously with at least the openings of the dielectric film 3 (107), the openings 6 communicate with the openings in substantially the same size.

In this embodiment, the openings 6 are also formed simultaneously with and communicate with the openings of the conductive layer (the metal foil 2). Therefore, the openings 6 have a form of through-holes between the metal foil 2, which is the same member as the electrode of the thin film capacitor, and the conductive film 4.

As in other embodiments explained later, openings communicating with the openings of the dielectric film 3 (107) can be formed in only one of the conductive layer (the conductive film 4) and the conductive layer (the metal foil 2).

The number and the arrangement of the openings 6 are determined with respect to the thin film capacitor 105 such that film peeling can be prevented against stress from all directions in a plane. Therefore, the number and the arrangement of the openings 6 are not limited to the example shown in FIG. 4B and are determined as appropriate according to, for example, the shape of the capacitor. The arrangement of the openings 6 does not always have to be at equal intervals.

At least one of the prepreg 7 from the rear surface side and the prepreg 13 from the front surface side is filled and an integrated prepreg is formed in the openings 6. A prepreg material is fluidized by heating and integration of the prepregs is improved.

Therefore, in the openings 6, the prepreg material functions as a reinforcing member that couples the sidewall of the dielectric film 3 (107) and the sidewall of the conductive layer (the conductive film 4 or the metal foil 2).

The prepreg material functioning as the reinforcing member keeps firm the coupling of the dielectric film and the conductive layer with force against film peeling on the interface between the dielectric film and the conductive layer. Therefore, it is possible to increase adhesive strength of the thin film capacitor material having weak adhesion.

### [Manufacturing Method]

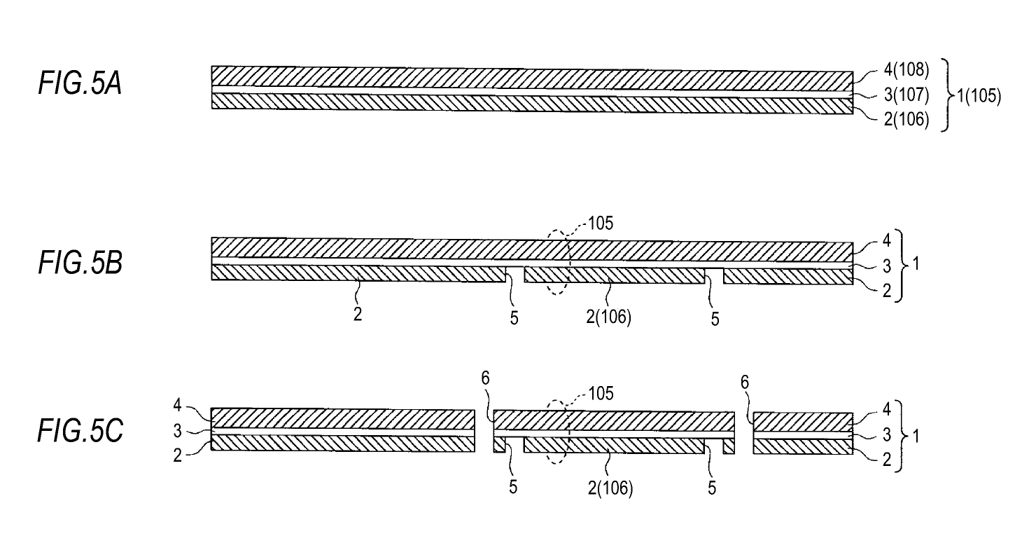

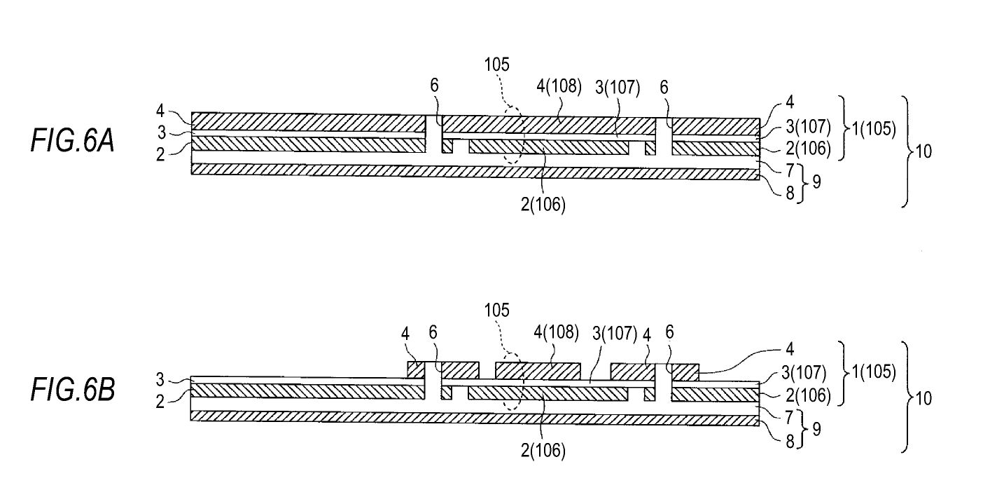

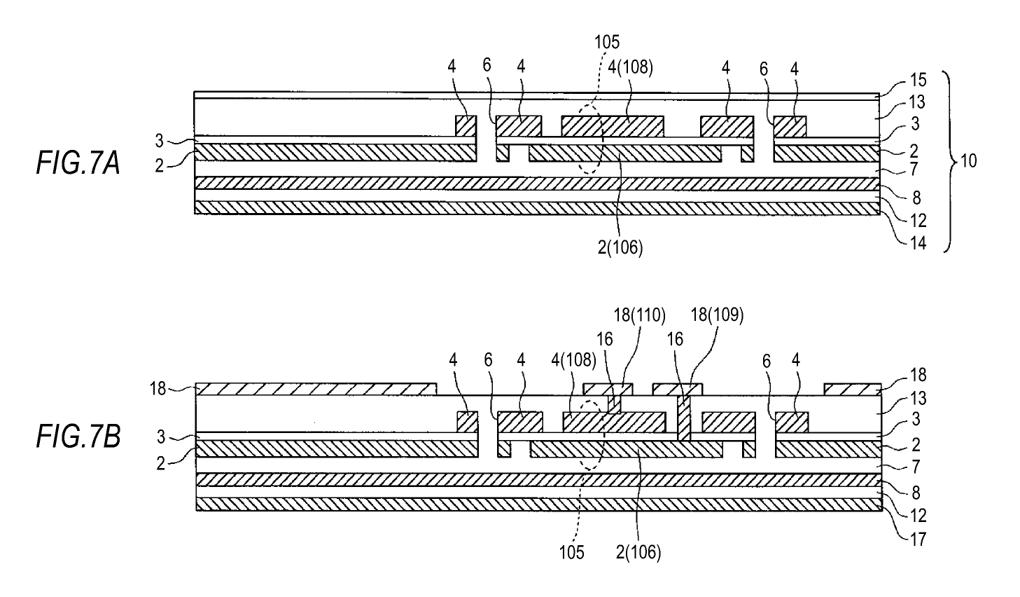

A method of manufacturing the mounting substrate including the thin film capacitor 105 having the structure shown in FIGS. 4A and 4B is explained with reference to sectional views of FIGS. 5A to 7B. FIGS. 5A to 5C are sectional views for explaining a manufacturing process for the thin film capacitor material formed separately from the mounting substrate. FIGS. 6A to 7B are sectional views for explaining a main manufacturing process for the mounting substrate starting from a sticking step for the thin film capacitor material. These sectional views are sectional views of the same portion as FIG. 4A.

In the following explanation of the manufacturing method, a representative manufacturing method in this embodiment is explained. However, manufacturing conditions and the like are not limited to the following explanation.

As shown in FIG. 5A, the thin film capacitor material 1 has a structure in which the metal foil 2, the dielectric film 3, and the conductive film 4 are laminated. The thin film capacitor material 1 is supplied to the manufacturing process as a sheet member in such a form.

The material of the metal foil 2 is not specifically limited. However, the metal foil 2 is formed of metal such as copper or nickel.

The material of the conductive film 4 is not specifically limited. However, the conductive film 4 is a single layer formed of metal such as copper or nickel or a laminated body formed of plural materials.

The material of the dielectric film 3 is not particularly limited. However, a crystalline dielectric film having a high relative dielectric constant formed of, for example, strontium titanate (SrTiO₃:STO), barium titanate (BaTiO₃:BTO), barium strontium titanate (BST), or lead titanate zirconate (PZT) is desirable.

In a step shown in FIG. 5B, a mask (not shown) for processing the metal foil 2 is formed by a dry film or the like and the metal foil 2 is processed using, for example, a chemical. Consequently, the metal foil 2 (106) functioning as the first electrode layer 106 is separated from the metal foil 2 around the metal foil 2 (106) via a separating section 5. Thereafter, when the dry film is removed, the patterning of the first electrode layer 106 in the thin film capacitor 105 ends.

In a step shown in FIG. 5C, the openings 6, which are a characteristic of this embodiment, are formed. For example, the metal foil 2, the dielectric film 3, and the conductive film 4 are processed using a drill or a laser beam to form the openings 6 (the through-holes). For example, in the example shown in FIG. 4B, eight openings 6 (through-holes) in total are provided in the portion of the conductive layer (the conductive film 4) surrounding the conductive film 4 functioning as the first electrode layer 106. The size of the openings 6 (the through-holes) may be equal in the metal foil 2 and the conductive film 4 or may be smaller in any one of the metal foil 2 and the conductive film 4.

According to the steps explained above, the partially-processed thin film capacitor material 1 is formed.

For example, the prepreg 7 and the copper foil 8 are already formed on a resin substrate 9 shown in FIG. 6A.

The thin film capacitor material 1 adjusted to a desired region is stuck together with a surface of the resin substrate 9, on which the prepreg 7 is formed, by a pressing method or the like. Consequently, a core substrate 10 including the thin film capacitor material 1 is formed.

At this point, a stuck-together surface of the thin film capacitor material 1 is stuck together on the metal foil 2 side subjected to patterning. The resin may flow to be filled in the through-holes (the openings 6) according to the sticking together.

Subsequently, the conductive film 4 is processed by, for example, a dry film opened in a desired region thereof to form a mask (not shown) for separating the second electrode layer 108. The conductive film 4 is processed using, for example, a chemical and, as shown in FIG. 6 B, the conductive film 4 (105) is formed. Thereafter, the dry film is removed. A cross section after the removal of the dry film is shown in FIG. 6B.

In a step shown in FIG. 7A, the prepregs 12 and 13 and the copper foils 14 and 15 are stuck together with the core substrate 10. The resin material of the prepregs flows into the openings 6 (the through-holes) according to the sticking together. The openings 6 are filled with the prepregs functioning as the reinforcing member. This makes it possible to improve adhesion.

In a step shown in FIG. 7B, the copper foil 15 (not shown) and the prepreg 13 are opened by laser processing to form via electrodes 16. As the via electrodes 16, there are the via electrode 16 formed in the prepreg 13 and connected to the conductive film 4 (the second electrode layer 108) and the via electrode 16 formed in the prepreg 13 and connected to the metal foil 2 (the first electrode layer 106) via the openings of the dielectric film 3.

Subsequently, the entire surfaces of the copper foils 14 and 15 are Cu grown to predetermined thickness by electrolytic plating to form the conductive film 18.

Subsequently, a mask (not shown) for processing the conductive film 18 is formed by, for example, a dry film opened in a desired region thereof. The conductive film 18 is processed using, for example, a chemical. Thereafter, the dry film is removed. At this point, a not-shown wire is formed on the conductive film 17 on the rear surface as well.

The conductive film 18 processed on the front surface side includes the conductive film 18 (106) connected to the first electrode layer 106 via the via electrode 16. The conductive film 18 includes the conductive film 18 (108) connected to the second electrode layer 108 via the via electrode 16. The conductive film 18 is also formed in, for example, an arrangement region of the IC 104 (FIG. 4A).

According to the manufacturing method explained above, a structure can be formed in which, after the thin film capacitor material 1 is stuck together with the core substrate 10 to form the prepreg 13, film peeling of the thin film capacitor 105 because of heating or the like less easily occurs. An additional step for the formation of the structure only has to be forming the openings 6 with a drill or a laser processing in the state of the thin film capacitor material 1. Therefore, an increase in cost is suppressed as much as possible.

### 4. Second Embodiment

### [Device Structure]

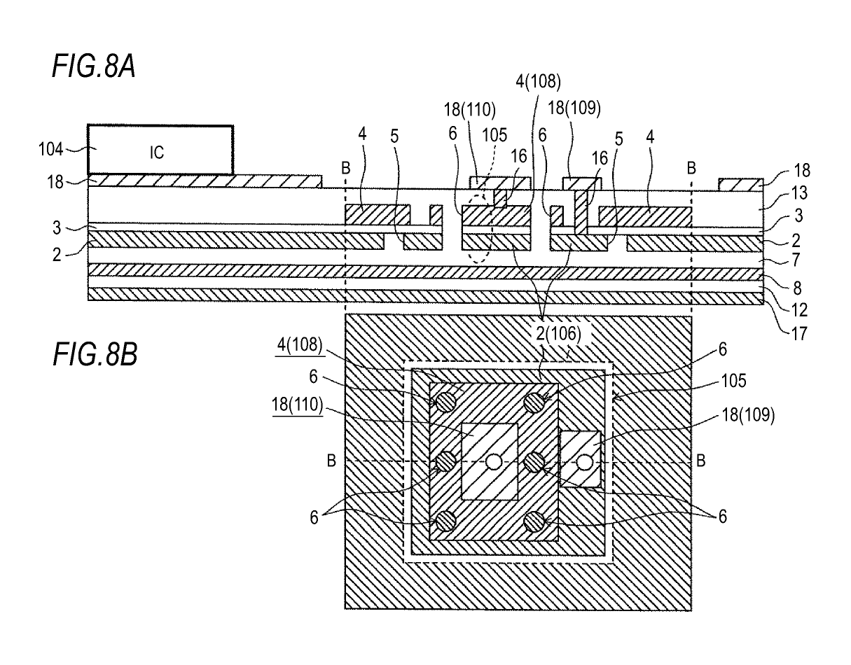

FIG. 8A is a sectional view of a thin film capacitor portion of a mounting substrate according to a second embodiment. The sectional view corresponds to the portion taken along line D-D in FIG. 1C. FIG. 8B is a transparent plane view taken along line B-B in FIG. 8A. The meaning of the transparent plane view is the same as the meaning of FIG. 3B with respect to FIG. 3A.

In the second embodiment, the positions of the through-holes (the openings 6) are changed from the periphery of the thin film capacitor 105 to the inside of the thin film capacitor 105. Specifically, the through-holes (the openings 6) are formed around the conductive film 18 (108) connected to the second electrode layer 108. As in the first embodiment, the openings 6 at this point are through-holes that pierce through the conductive film 4 (108) functioning as the second electrode layer 108, the dielectric film 3 (107), and the metal foil 2 (106) functioning as the first electrode layer 106. Resin (a prepreg material) is filled in the through-holes to cause the prepreg material to function as a reinforcing member for preventing film peeling of the thin film capacitor 105 in the same manner as in the first embodiment.

The configuration except the positions of the through-holes (the openings 6) is already explained with reference to FIGS. 4A and 4B. Therefore, explanation of the configuration is omitted.

In the manufacturing of the mounting substrate according to the second embodiment, the positions where the through-holes (the openings 6) are formed in the step in FIG. 5C are different from those in the first embodiment. Therefore, in this embodiment, basically, the manufacturing method already explained with reference to FIGS. 5A to 7B can be suitably applied.

### 5. Third Embodiment

In the first and second embodiments, all the regions in the through-holes (the openings 6) are filled with the prepreg material to prevent film peeling.

On the other hand, a third embodiment indicates that core portions of the through-holes (the openings 6) do not have to be resin such as the prepreg material and may be, for example, a conductive member.

This form can be applied to both the first and second embodiments. However, in the second embodiment, since it is necessary to prevent short circuit between the electrodes of the thin film capacitor 105, a portion directly in contact with the sidewall of the capacitor electrode around the core portions needs to be resin such as a prepreg. On the other hand, in the first embodiment, all the regions in the through-holes (the openings 6) can also be filled with conductive materials. This form is explained again in an eighth embodiment later.

Application of the use of conductive materials for core portions of through-holes to the second embodiment is explained below with reference to the drawings.

### [Device Structure]

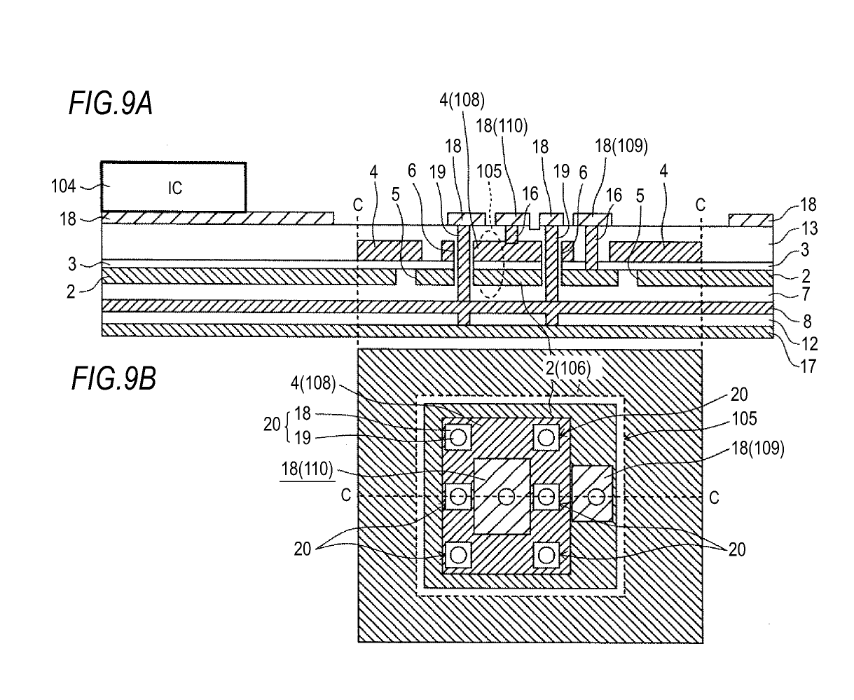

FIG. 9A is a sectional view of a thin film capacitor portion of amounting substrate according to a third embodiment. The sectional view corresponds to the portion taken along line D-D in FIG. 1C. FIG. 9B is a transparent plane view taken along line C-C of FIG. 9A. The meaning of the transparent plane view is the same as the meaning of FIG. 3B with respect to FIG. 3A.

In the third embodiment, the positions of six through-holes (openings 6) in total provided in this example are substantially the same as those in the second embodiment.

Via electrodes 19 are inserted through core portions of the through-holes (the openings 6). The resin of the prepreg 7 or the prepreg 13 is filled in gaps around the via electrodes 19. Consequently, electric short circuit between the electrodes of the thin film capacitor 105 and between the electrodes and the via electrodes 19 is prevented.

The via electrodes 19 can also be set electrically floating. However, as a preferred form, the via electrodes 19 are used as a part of wires that transmit a voltage, a signal, and the like. Specifically, the via electrodes 19 are connected to the copper foil 8 in the lower layer and connected to a wiring layer including the conductive film 18 in the upper layer.

In an example shown in FIGS. 9A and 9B, the copper foil 8 and the conductive film 17 are also connected by via electrodes. However, this is not indispensable. A configuration is also possible in which a certain via electrode 19 is connected to the copper foil 8 and the other via electrodes 19 are connected to the conductive film 17 in the lower layer through vias insulated from the copper foil 8.

In such a configuration, there is an advantage that the insides of the through-holes (the openings 6) can be effectively used as portions through which electrode vias are inserted. After the via electrodes 19 are inserted, peeling strength is higher than that in the first and second embodiments.

On the other hand, when there is no room in the area of the thin film capacitor 105, the area of a capacitative device could change because of the through-holes. In that case, it is also possible to take measures by increasing the size of the through-holes.

A manufacturing method is the same as the manufacturing method according to the second embodiment. In the manufacturing method, it is necessary to form the via electrodes 19. However, the via electrodes 19 can be formed simultaneously with the formation of the via electrodes 16. In that case, a via opening pattern only has to be changed. There is no substantial addition of a manufacturing step.

### 6. Fourth Embodiment

Another manufacturing method provided by a fourth embodiment is explained below. The manufacturing method can be applied to a structure in which the through-holes (the openings 6) are filled with resin. In that sense, the manufacturing method is a manufacturing method applicable to the first and second embodiments. In the following explanation, the fourth embodiment is explained with reference to, as an example, manufacturing of a device structure same as that in the first embodiment. Drawings of the device structure are present and comparison of the device structure with that in the first embodiment is easy.

The fourth embodiment is characterized in that filling of the rein in the through-holes (the openings 6) is performed in the thin film capacitor material 1 before sticking together with the mounting substrate.

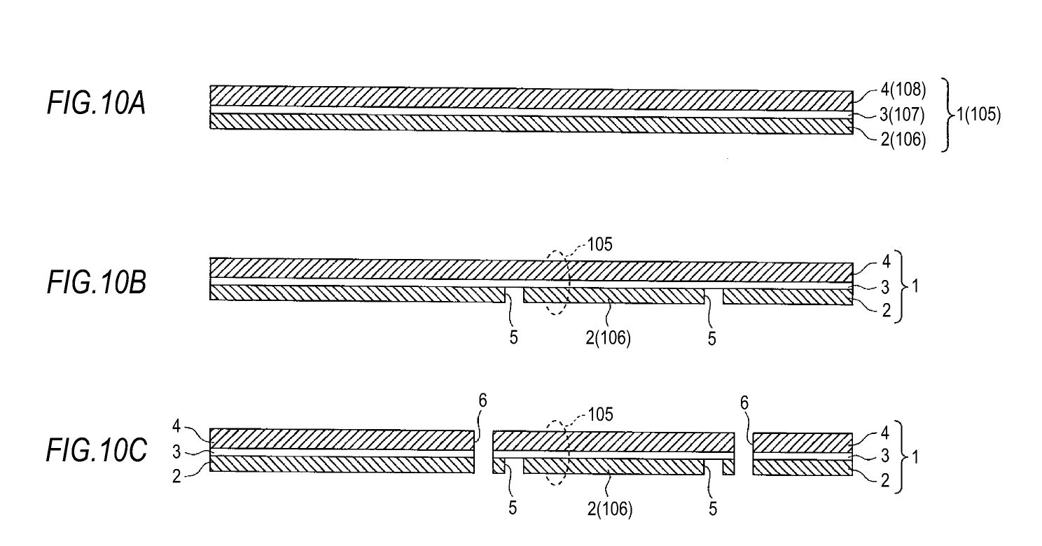

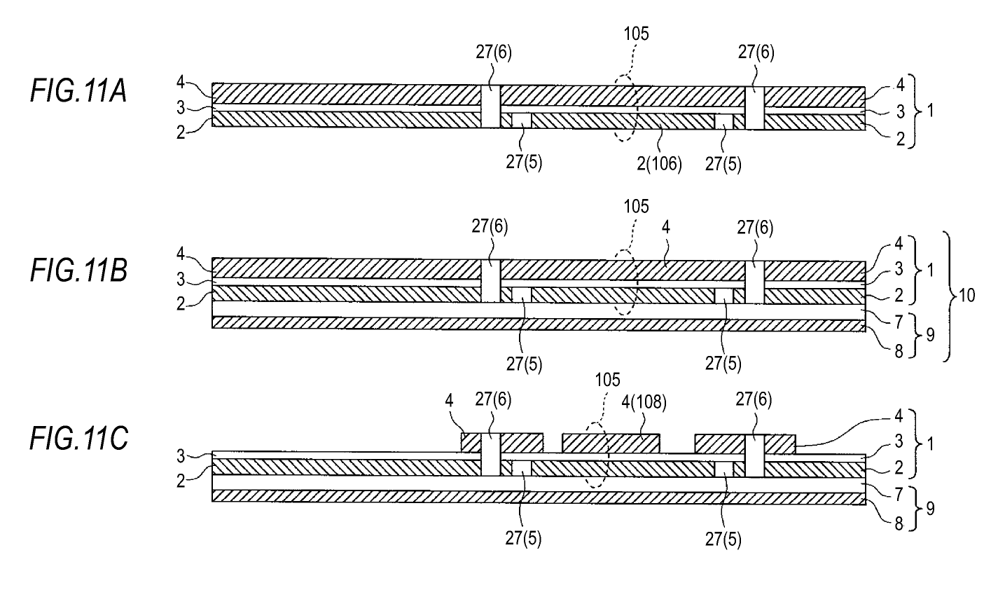

FIGS. 10A to 11A are sectional views for explaining a manufacturing process for a thin film capacitor material formed separately from a mounting substrate. FIGS. 11B and 11C are sectional views for explaining a process from a sticking step of the thin film capacitor material to the end of processing of electrodes of the thin film capacitor. The sectional views are sectional views of a portion same as the portion shown in FIG. 4A.

In the following explanation of the manufacturing method, a representative manufacturing method in this embodiment is explained. However, manufacturing conditions and the like are not limited to the following explanation.

As shown in FIG. 10A, the thin film capacitor material 1 has a structure in which the metal foil 2, the dielectric film 3, and the conductive film 4 are laminated. The thin film capacitor material 1 is supplied to the manufacturing process as a sheet member in such a form.

A material of the metal foil 2 is not specifically limited. However, the metal foil 2 is formed of metal such as copper or nickel.

The material of the conductive film 4 is not specifically limited. However, the conductive film 4 is a single layer formed of metal such as copper or nickel or a laminated body formed of plural materials.

The material of the dielectric film 3 is not particularly limited. However, a crystalline dielectric film having a high relative dielectric constant formed of, for example, strontium titanate (SrTiO₃:STO), barium titanate (BaTiO₃:BTO), barium strontium titanate (BST), or lead titanate zirconate (PZT) is desirable.

In a step shown in FIG. 10B, a mask (not shown) for processing the metal foil 2 is formed by a dry film or the like and the metal foil 2 is processed using, for example, a chemical. Consequently, the metal foil 2 (106) functioning as the first electrode layer 106 is separated from the metal foil 2 around the metal foil 2 (106) via the separating section 5. Thereafter, when the dry film is removed, the patterning of the first electrode layer 106 in the thin film capacitor 105 ends.

In a step shown in FIG. 10C, the openings 6 are formed. For example, the metal foil 2, the dielectric film 3, and the conductive film 4 are processed using a drill or a laser beam to form the openings 6 (the through-holes). For example, in the example shown in FIG. 4B, eight openings 6 (through-holes) in total are provided in the portion of the conductive layer (the conductive film 4) surrounding the conductive film 4 functioning as the first electrode layer 106. Although different from positions shown in the figure, when the positions of the openings 6 are the same as the positions in the second embodiment, the openings 6 (the through-holes) are formed in the thin film capacitor 105 further on the inner side than the separating section 5. The size of the openings 6 (the through-holes) may be equal in the metal foil 2 and the conductive film 4 or may be smaller in any one of the metal foil 2 and the conductive film 4.

A step shown in FIG. 11A is provided anew in this embodiment. In this step, resin 27 is filled in the through-holes (the openings 6) and a processing section (the separating section 5) for a meal foil by a screen printing method or the like and the thin film capacitor material 1 is formed.

As a resin material, for example, polyimide, epoxy, BCB, or fluorine resin is desirable.

In the step, when the resin remains on the conductive film 4, the remaining resin may be left as it is as long as a problem in manufacturing does not occur. Alternatively, the remaining resin may be scraped by an extremely soft grinding pad like buffing and removed by planarization.

According to the steps explained above, the partially-processed thin film capacitor material 1 in which the resin 27 is filled is formed.

For example, the prepreg 7 and the copper foil 8 are already formed on a resin substrate 9 shown in FIG. 11B.

The thin film capacitor material 1 adjusted to a desired region is stuck together with a surface of the resin substrate 9, on which the prepreg 7 is formed, by a pressing method or the like. Consequently, the core substrate 10 including the thin film capacitor material 1 is formed.

At this point, a stuck-together surface of the thin film capacitor material 1 is stuck together on the metal foil 2 side subjected to patterning. The resin 27 and the prepreg 7 in the through-holes (the openings 6) are joined by the sticking together. When the resin 27 and the resin material of the prepreg 7 are the same, the resin 27 and the prepreg 7 may flow to be integrated.

Subsequently, the conductive film 4 is processed by, for example, a dry film opened in a desired region thereof to form a mask (not shown) for separating the second electrode layer 108. The conductive film 4 is processed using, for example, a chemical and, as shown in FIG. 11C, the conductive film 4 (105) is formed. Thereafter, the dry film is removed. Across section after the removal of the dry film is shown in FIG. 11C.

The following manufacturing method is the same as the manufacturing method shown in FIGS. 7A and 7B.

In this embodiment, the step of filling the resin 27 is added. However, film peeling strength is high even in a state before the thin film capacitor material 1 is stuck together. Therefore, a capacitor structure robust against stress during handling and during sticking together of the thin film capacitor material 1 can be obtained.

### 7. Fifth Embodiment

Another manufacturing method provided by a fifth embodiment is explained below. This manufacturing method can be applied to a structure in which the through-holes (the openings 6) are filled with resin. In that sense, the manufacturing method is a manufacturing method applicable to the first and second embodiments. Alternatively, the manufacturing method can also be applied when the core portions of the openings 6 are formed as a conductive layer as in the third embodiment. In the following explanation, the fifth embodiment is explained with reference to, as an example, manufacturing of a device structure same as that in the first embodiment. Drawings of the device structure are present and comparison of the device structure with that in the first embodiment is easy.

The fifth embodiment is characterized in that opening of the through-holes (the openings 6) is performed after the thin film capacitor material 1 is stuck together with the resin substrate 9.

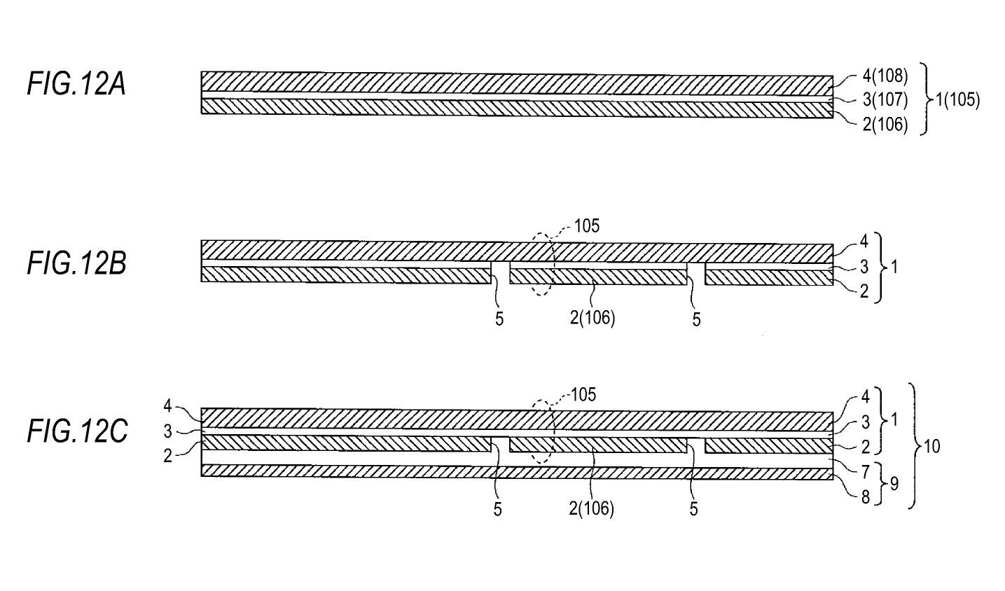

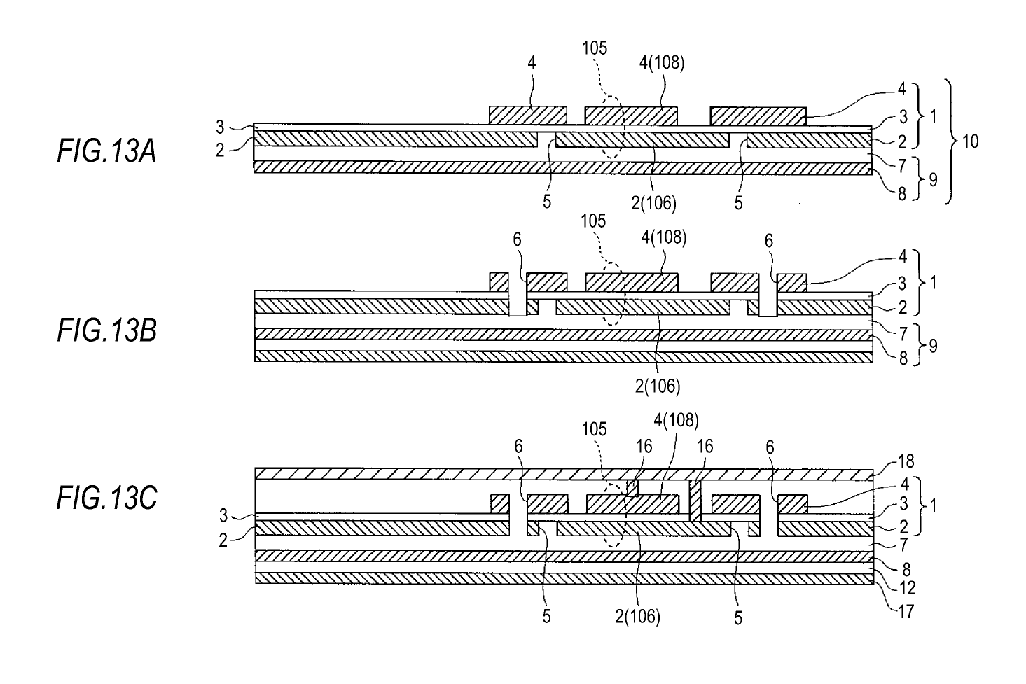

FIGS. 12A and 12B are sectional views for explaining a manufacturing process for a thin film capacitor material formed separately from a mounting substrate. FIGS. 12C to 13C are sectional views for explaining a main process for manufacturing a mounting substrate starting from a sticking step of the thin film capacitor material. The sectional views are sectional views of a portion same as the portion shown in FIG. 4A.

In the following explanation of the manufacturing method, a representative manufacturing method in this embodiment is explained. However, manufacturing conditions and the like are not limited to the following explanation.

As shown in FIG. 12A, the thin film capacitor material 1 has a structure in which the metal foil 2, the dielectric film 3, and the conductive film 4 are laminated. The thin film capacitor material 1 is supplied to the manufacturing process as a sheet member in such a form.

A material of the metal the metal foil 2 is not specifically limited. However, the metal foil 2 is formed of metal such as copper or nickel.

The material of the conductive film 4 is not specifically limited. However, the conductive film 4 is a single layer formed of metal such as copper or nickel or a laminated body formed of plural materials.

The material of the dielectric film 3 is not particularly limited. However, a crystalline dielectric film having a high relative dielectric constant formed of, for example, strontium titanate (SrTiO₃:STO), barium titanate (BaTiO₃:BTO), barium strontium titanate (BST), or lead titanate zirconate (PZT) is desirable.

In a step shown in FIG. 12B, a mask (not shown) for processing the metal foil 2 is formed by a dry film or the like and the metal foil 2 is processed using, for example, a chemical. Consequently, the metal foil 2 (106) functioning as the first electrode layer 106 is separated from the metal foil 2 around the metal foil 2 (106) via the separating section 5. Thereafter, when the dry film is removed, the patterning of the first electrode layer 106 in the thin film capacitor 105 ends.

According to the steps explained above, the thin film capacitor material 1 in which an opening is not opened yet is formed.

For example, the prepreg 7 and the copper foil 8 are already formed on the resin substrate 9 shown in FIG. 12C.

The thin film capacitor material 1 adjusted to a desired region is stuck together with a surface of the resin substrate 9, on which the prepreg 7 is formed, by a pressing method or the like. Consequently, the core substrate 10 including the thin film capacitor material 1 is formed.

At this point, a stuck-together surface of the thin film capacitor material 1 is stuck together on the metal foil 2 side subjected to patterning.

Subsequently, the conductive film 4 is processed by, for example, a dry film opened in a desired region thereof to form a mask (not shown) for separating the second electrode layer 108. The conductive film 4 is processed using, for example, a chemical and, as shown in FIG. 13A, the conductive film 4 (105) is formed. Thereafter, the dry film is removed. Across section after the removal of the dry film is shown in FIG. 13A.

In a step shown in FIG. 13B, the openings 6, which are a characteristic of this embodiment, are formed. For example, the metal foil 2, the dielectric film 3, and the conductive film 4 are processed using a drill or a laser beam to form the openings 6 (the through-holes). For example, when the openings 6 (the through-holes) are the same as those shown in FIG. 4B, the eight openings 6 (through-holes) in total are provided in the portion of the conductive layer (the conductive film 4) surrounding the conductive film 4 functioning as the first electrode layer 106. The size of the openings 6 (the through-holes) may be equal in the metal foil 2 and the conductive film 4 or may be smaller in any one of the metal foil 2 and the conductive film 4.

Thereafter, steps same as the steps shown in FIGS. 7A and 7B in the first embodiment are performed.

First, the prepregs 12 and 13 and a copper foil (not shown) are stuck together with the core substrate 10. A resin material of the prepregs flows into the openings 6 (the through-holes) according to the sticking together of the copper foil. The openings 6 are filled with the prepregs functioning as a reinforcing member. Consequently, it is possible to improve adhesion.

Subsequently, the via electrodes 16 are formed by a method same as the method in the first embodiment (FIG. 7B) and the conductive film 18 is formed on the via electrodes 16. At this point, the conductive film 17 is simultaneously formed on the rear surface. FIG. 13C is a sectional view immediately after the formation of the conductive films 17 and 18.

Thereafter, as in the first embodiment, the conductive film 18 and the like are patterned to complete the mounting substrate.

In the embodiments explained above, the openings 6 are formed as the through-holes that pierce through all of the metal foil 2, the dielectric film 3, and the conductive film 4.

On the other hand, even if openings are not through-holes, improvement of film peeling strength can be realized simply by opening one of the metal foil 2 and the conductive film 4 and the dielectric film 3.

### 8. Sixth Embodiment

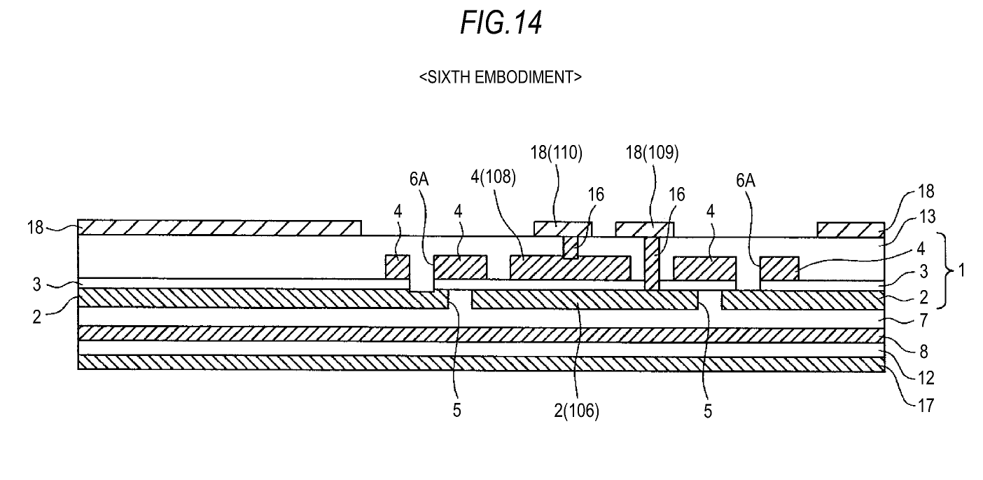

FIG. 14 is a sectional view of a mounting substrate according to a sixth embodiment.

In the sectional view, openings 6A opened in the conductive film 4 and the dielectric film 3 are provided in the positions where the through-holes (the openings 6) are provided in the first embodiment. A manufacturing method according to the sixth embodiment is different from the manufacturing method according to the first embodiment in that the opening of the openings 6A is stopped at a point when the surface of the metal foil 2 is exposed. Otherwise, the manufacturing method is the same as the manufacturing method according to the first embodiment.

Unlike the separating section 5 for the electrodes, the openings 6A is opened in the dielectric film 3 as well. Therefore, for example, the resin of the prepreg 13 functions as a reinforcing member to couple inner side walls of openings of the dielectric film 3 and inner side walls of openings of the conductive film 4. Therefore, film peeling strength of the thin film capacitor 105 is improved.

### 9. Seventh Embodiment

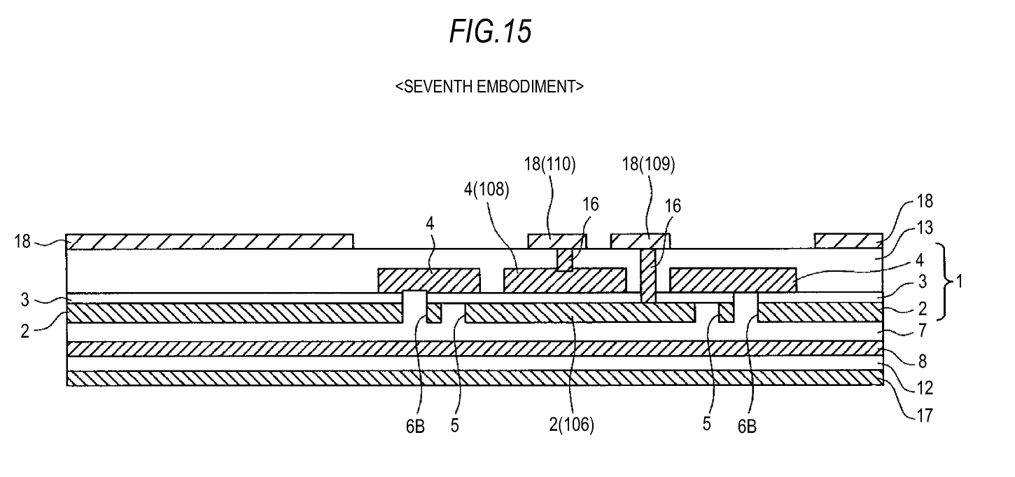

FIG. 15 is a sectional view of a mounting substrate according to a seventh embodiment.

In the sectional view, openings 6B opened in the metal foil 2 and the dielectric film 3 are provided in the positions where the through-holes (the openings 6) are provided in the fourth embodiment. Before the thin film capacitor material 1 is stuck together with a resin substrate, the openings 6B are opened. A method of forming the thin film capacitor material 1 according to the seventh embodiment is different from the method of forming the thin film capacitor material 1 according to the fourth embodiment in that the opening of the openings 6B is stopped at a point when the surface of the metal foil 2 is exposed and that the resin 27 is not filled. Otherwise, the method is the same as the method according to the fourth embodiment.

Unlike the separating section 5 for the electrodes, in the openings 6B, the dielectric film 3 is also opened. Therefore, for example, the resin of the prepreg 13 functions as a reinforcing member to couple inner side walls of openings of the dielectric film 3 and inner side walls of openings of the metal foil 2. Therefore, film peeling strength of the thin film capacitor 105 is improved.

In the sixth and seventh embodiments, the differences from the first and fourth embodiments are mainly explained. However, as in the second embodiment, the forming positions of the openings 6A and 6B can also be provided in a surface on which the MIM structure of the thin film capacitor 105 is formed. In that case, an occupied area of the capacitor is determined taking into account a decrease in a value of the capacitor due to the formation of the openings.

### 10. Eighth Embodiment

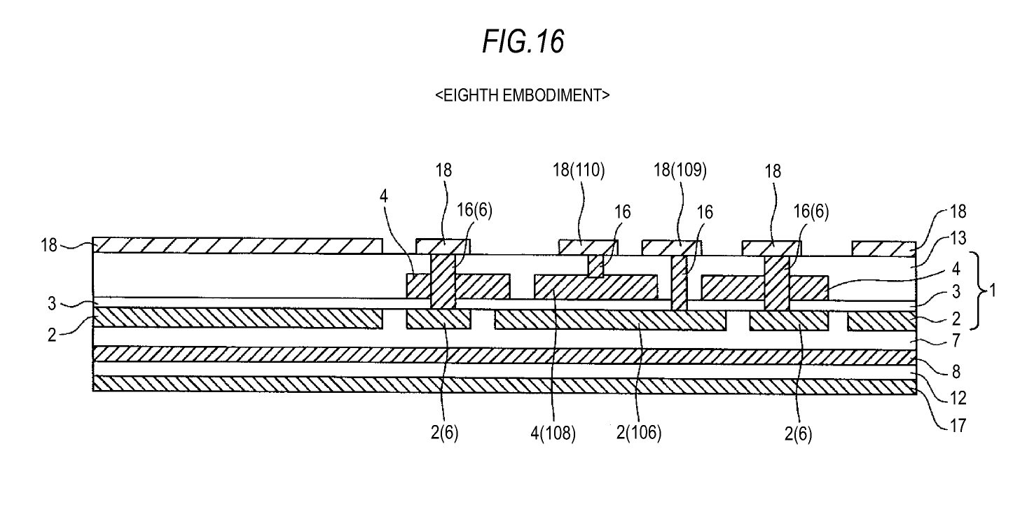

FIG. 16 is a sectional view of a mounting substrate according to an eighth embodiment.

In the eighth embodiment, the opening of the openings 6 shown in FIG. 13B in the manufacturing according to the fifth embodiment is stopped when the metal foil 2 is exposed. Therefore, the openings after the formation are like the openings 6A shown in FIG. 14. Since the openings 6A are formed after the thin film capacitor material 1 is stuck together with the substrate as in the fifth embodiment, the openings 6A communicate with the openings of the prepreg 13 on the front surface. The via electrodes 16 are embedded and formed in such openings. The conductive films 18 and 17 are formed according to a method same as the method according to the first and fifth embodiments.

### 11. Ninth Embodiment

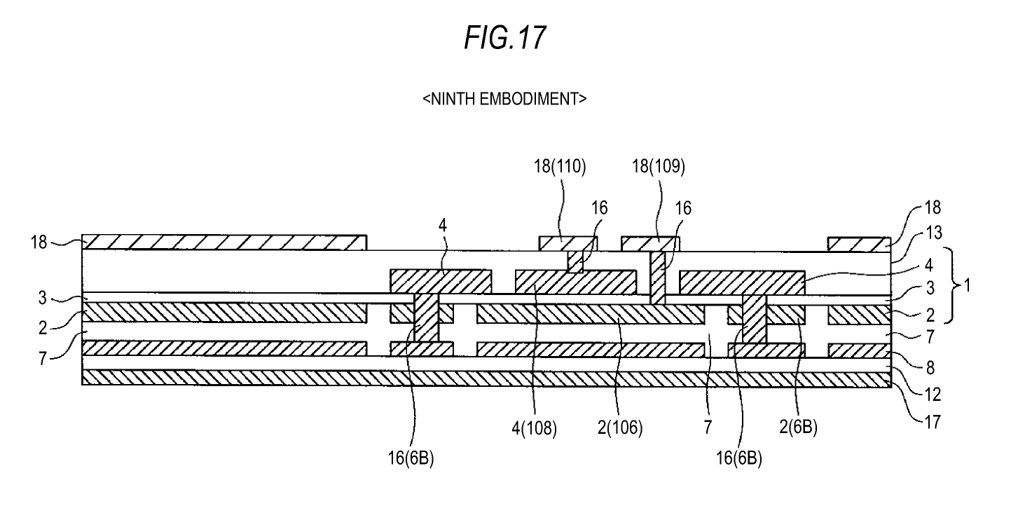

FIG. 17 is a sectional view of a mounting substrate according to a ninth embodiment.

In the ninth embodiment, as shown in FIG. 17, the mounting substrate has a structure in which the via electrodes 16 (6B) are embedded in openings same as the openings 6B shown in FIG. 15.

To form such a structure, for example, a method explained below can be adopted.

In a forming process for the thin film capacitor material 1, the openings 6B opened in not only the metal foil 2 but also in the dielectric film 3 are formed and filled with a conductive substance in advance.

On the other hand, in the resin substrate 9 on the side on which the thin film capacitor material 1 is stuck, openings that pierce through the prepreg 7 and reach the copper foil 8 are formed and filled with a conductive substance.

When the thin film capacitor material 1 is stuck together with such a resin substrate 9, the two conductive substances are coupled and the via electrodes 16 (6B) are formed.

Formation of the prepreg 13, the via electrodes 16, and the conductive film 18 on the conductive film 4 side is performed in the same manner as the formation in the other embodiments.

According to the eighth and ninth embodiments, even if openings are not through-holes, formation of a more robust reinforcing member by a conductive material is possible. In these embodiments, since the reinforcing member is the conductive material, the positions of the openings are limited to the arrangement further on the outer side than the thin film capacitor 105.

The via electrodes 16 that pierce through the openings may be used as a part of wires that transmit a voltage, a signal, and the like as in, for example, the third embodiment.

### 12. Modification 1

### First Embodiment

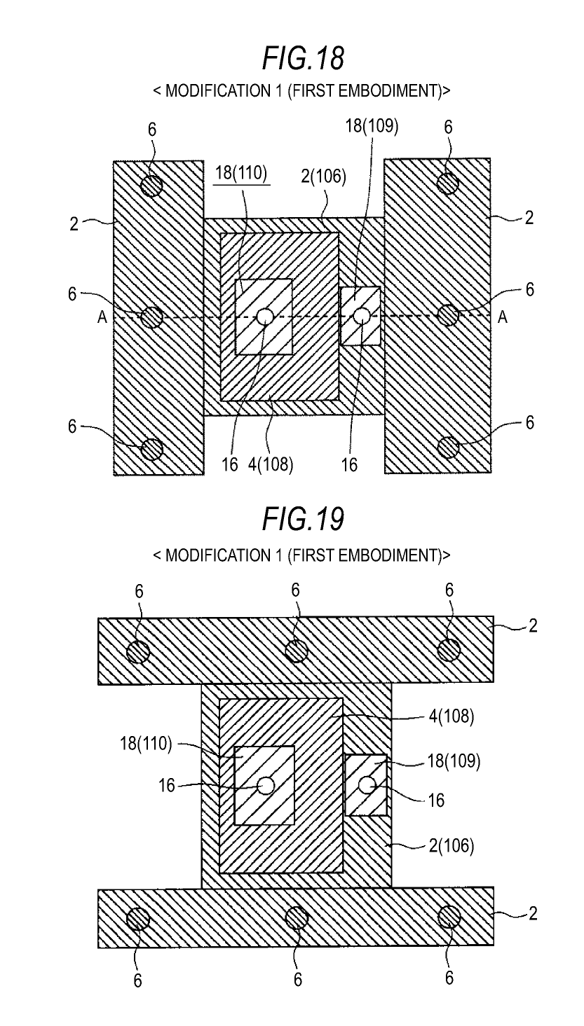

FIGS. 18 and 19 are transparent plane views of a modification 1 of the first embodiment.

In the modification 1, the openings 6 are formed using a nearby wiring layer even if a pattern of the metal foil 2 surrounding the thin film capacitor 105 is not specifically provided.

In FIG. 18, an internal wire (the metal foil 2) in the longitudinal direction on the paper surface is used to provide the openings 6 in the internal wire.

In FIG. 19, an internal wire (the metal foil 2) in the lateral direction on the paper surface is used to provide the openings 6 in the internal wire.

As in the third embodiment, for example, a further modification for forming via electrodes in core portions in the openings 6 and a further modification for filling conductive materials in the openings 6 to form via electrodes are possible.

### 13. Other Modifications

In the embodiments and the modifications explained above, the electronic component such as the IC 104 is mounted on the upper surface (the substrate surface) of the mounting substrate 103. However, a form of double-sided mounting in which an electronic component is also mounted on the lower surface (the other substrate surface) of the mounting substrate 103 may be adopted.

In the embodiments, the first electrode layer 106 and the second electrode layer 108 are formed in a rectangular shape. However, a plane shape of the first electrode layer 106 and the second electrode layer 108 is arbitrary. Openings formed by through-holes or grooves may have any plane view shape (a sectional shape orthogonal to a through axis) such as circular, elliptical, and polygonal.

Besides, various modifications are possible without departing from the spirit of the technique of the embodiment of the present disclosure.

According to the embodiments and the modifications, it is possible to prevent peeling due to the influence of stress near a capacitance generating section (the thin film capacitor material 1). This effect can be obtained by filling resin or conductive materials in through-holes and/or grooves of two electrode layers and increasing adhesive strength by the filled film. It is possible to prevent peeling between a dielectric film and the two electrode layers due to stress or the like in a manufacturing process and eliminate a failure in manufacturing due to the peeling.

Since the manufacturing process is a standard process of a substrate forming process, a substrate can be formed without the necessity of an additional step. Therefore, it is possible to easily form the substrate at low cost.

The present disclosure contains subject matter related to that disclosed in Japanese Priority Patent Application JP 2011-079816 filed in the Japan Patent Office on Mar. 31, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film capacitor comprising:
two electrode layers;
a dielectric film interposed between the two electrode layers;
an opening that pierces through, together with the dielectric film, in the thickness direction, any one of the two electrode layers or a conductive layer in the same level adjacent to one of the two electrode layers; and
a reinforcing member that couples, in the opening, a side surface of the dielectric film to a side surface of the one electrode layer or the conductive layer.

2. A mounting substrate comprising a laminated structure in which conductive films and insulating films are alternately laid one on top of another, wherein
a thin film capacitor is formed in the laminated structure, and
the thin film capacitor includes:
two electrode layers;
a dielectric film interposed between the two electrode layers;
an opening that pierces through, together with the dielectric film, in the thickness direction, any one of the two electrode layers or a conductive layer in the same level adjacent to the one of the two electrode layers; and
a reinforcing member that couples, in the opening, a side surface of the dielectric film to a side surface of the one electrode layer or the conductive layer.

3. The mounting substrate according to claim 2, wherein the reinforcing member is an insulating material.

4. The mounting substrate according to claim 3, wherein the insulating material is an inter-layer resin, which is interposed between the conductive films, flowing into the opening.

5. The mounting substrate according to claim 4, wherein a plurality of openings are provided in a capacitor region where the two electrode layers overlap.

6. The mounting substrate according to claim 5, wherein the opening is a through-hole that pierces through the two electrode layers and the dielectric film.

7. The mounting substrate according to claim 6, wherein a conductive material is formed in a core portion in the through-hole and an insulating material functioning as the reinforcing member is filled in a gap between the conductive material and an inner wall of the through-hole.

8. The mounting substrate according to claim 7, wherein the conductive material in the core portion in the through-hole is a via electrode that pierces through at least one of the insulating films in a thickness direction and connects a pair of the conductive films in the laminated structure.

9. The mounting substrate according to claim 2, wherein the opening is provided in a conductive layer in the same level as the two electrode layers and being separated from the two electrode layers.

10. The mounting substrate according to claim 9, wherein a conductive material is filled in the opening as the reinforcing member.

11. The mounting substrate according to claim 10, wherein the conductive material is a via electrode that pierces through at least one of the insulating films in a thickness direction and connects a pair of the conductive films in the laminated structure.

12. The mounting substrate according to claim 9, wherein the reinforcing member is an insulating material.

13. The mounting substrate according to claim 12, wherein the insulating material is an inter-layer resin, which is interposed between the conductive films, flowing into the opening.

14. A method of manufacturing a mounting substrate, comprising:
laminating a conductive layer functioning as a first electrode layer, a dielectric film layer, and a conductive layer functioning as a second electrode layer and forming a thin film capacitor material through formation of the first electrode layer by processing of one of the conductive layers;
sticking together the thin film capacitor material with a core substrate from a side of the first electrode layer;
opening, in the thin film capacitor material before or after the sticking together, the conductive layer of one of the first electrode layer and the second electrode layer or a conductive layer in the same level adjacent to the conductive layer and forming an opening to pierce through at least the dielectric film in the thickness direction; and
forming, in the thin film capacitor material, a reinforcing member that couples a sidewall in the opening of the conductive layer of any one of the first electrode layer and the second electrode layer or the conductive layer in the same level and a sidewall in the opening of the dielectric film.

15. The method of manufacturing a mounting substrate according to claim 14, wherein the reinforcing member is formed by causing a resin material formed on a surface of the core substrate to flow in the opening in the sticking together the thin film capacitor material with the core substrate.

16. The method of manufacturing a mounting substrate according to claim 14, further comprising forming the reinforcing member on the thin film capacitor material in advance before the sticking together.

17. The method of manufacturing a mounting substrate according to claim 14, further comprising:
forming the opening with processing from a surface after the sticking together; and
filling the opening with a resin material to form the reinforcing member formed of the resin material.

18. The method of manufacturing a mounting substrate according to claim 17, further comprising further processing, after filling the resin material functioning as the reinforcing member in the opening, a core portion in the opening and filling a core space formed by the processing with a conductive material to leave the resin material functioning as the reinforcing member around the conductive material.
